(19) United States
(12) Patent Application Publication
(10) Pub. No.: US 2026/0107767 A1
(43) Pub. Date: Apr. 16, 2026

(54) SEMICONDUCTOR DEVICE

(71) Applicant: Mitsubishi Electric Corporation, Tokyo (JP)

(72) Inventor: Ryosuke YABUKI, Tokyo (JP)

(73) Assignee: Mitsubishi Electric Corporation, Tokyo (JP)

(21) Appl. No.: 19/253,433

(22) Filed: Jun. 27, 2025

(30) Foreign Application Priority Data
Oct. 15, 2024 (JP) 2024-180225

(51) Int. Cl. H01L 23/367; H01L 23/00; H01L 23/31; H01L 23/498; H01L 25/065

(52) U.S. Cl. CPC H10W 40/22; H10W 70/479; H10W 90/00; H10W 72/884; H10W 74/114; H10W 90/734; H10W 90/755

(57) ABSTRACT

A semiconductor device according to the present disclosure includes: an insulating substrate; a semiconductor element bonded to a surface on one side of the insulating substrate; and a heat sink bonded to a surface on the other side of the insulating substrate, wherein the heat sink has at least one groove in a surface on the other side thereof opposite a surface on the one side thereof to which the insulating substrate is bonded, and the at least one groove is not located in each of portions of the surface on the other side of the heat sink located on opposite sides in a length direction of the at least one groove or in a portion of the surface on the other side of the heat sink located on one side in the length direction of the at least one groove.

### BACKGROUND

### Technical Field

The present disclosure relates to semiconductor devices.

### Description of the Background Art

A power module is one example of a semiconductor device. The power module includes semiconductor chips, insulating substrates, a base plate, wires, terminals, solder connecting them, and the like.

In Japanese Patent Application Laid-Open No. 2016-096188, for example, a heat sink for an insulating substrate has, in a central portion in a longitudinal direction thereof, a linear groove extending along a transverse direction thereof to enable adjustment of warpage of the insulating substrate, so that the insulating substrate can be flattened or can have a warpage amount reduced to a slight amount in a predetermined range.

In the conventional technology, the heat sink has, in the central portion in the longitudinal direction thereof, the linear groove extending along the transverse direction thereof, so that the groove acts to suppress warpage of the insulating substrate, but there has been concern about reduction in strength of the heat sink.

### SUMMARY

It is an object of the semiconductor device according to the present disclosure to provide a heat sink capable of suppressing reduction in strength thereof while suppressing warpage of an insulating substrate and the heat sink.

A semiconductor device according to the present disclosure includes: an insulating substrate; a semiconductor element bonded to a surface on one side of the insulating substrate; and a heat sink bonded to a surface on the other side of the insulating substrate, wherein the heat sink has at least one groove in a surface on the other side thereof opposite a surface on the one side thereof to which the insulating substrate is bonded, and the at least one groove is not located in each of portions of the surface on the other side of the heat sink located on opposite sides in a length direction of the at least one groove or in a portion of the surface on the other side of the heat sink located on one side in the length direction of the at least one groove.

According to the semiconductor device according to the present disclosure, the heat sink is grooved so that an end portion remains without being subjected to grooving, and thus optimization of warpage and securement of a strength of the heat sink can both be achieved. Furthermore, since the strength of the heat sink can be maintained, the heat sink itself can be thinned to enable reduction in cost.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to Embodiment 1;

FIG. 2 is a perspective view of a heat sink of the semiconductor device according to Embodiment 1;

FIG. 3 is a bottom view of the heat sink of the semiconductor device according to Embodiment 1;

FIG. 4 is a cross-sectional view of the heat sink of the semiconductor device according to Embodiment 1;

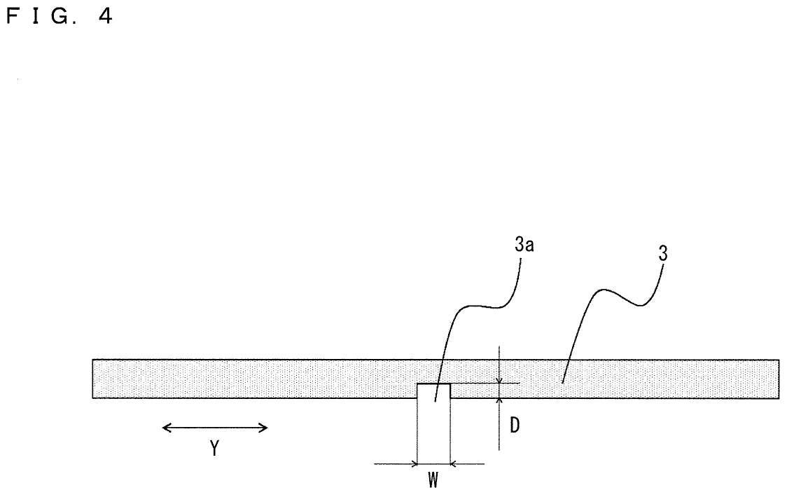

FIG. 5 is a cross-sectional view of a semiconductor device according to a modification of Embodiment 1;

FIG. 6 is a cross-sectional view of a semiconductor device according to a modification of Embodiment 1; and

FIG. 7 is a bottom view of a heat sink of a semiconductor device according to a modification of Embodiment 1.

### DESCRIPTION OF THE PREFERRED EMBODIMENTS

### 1. Embodiment 1

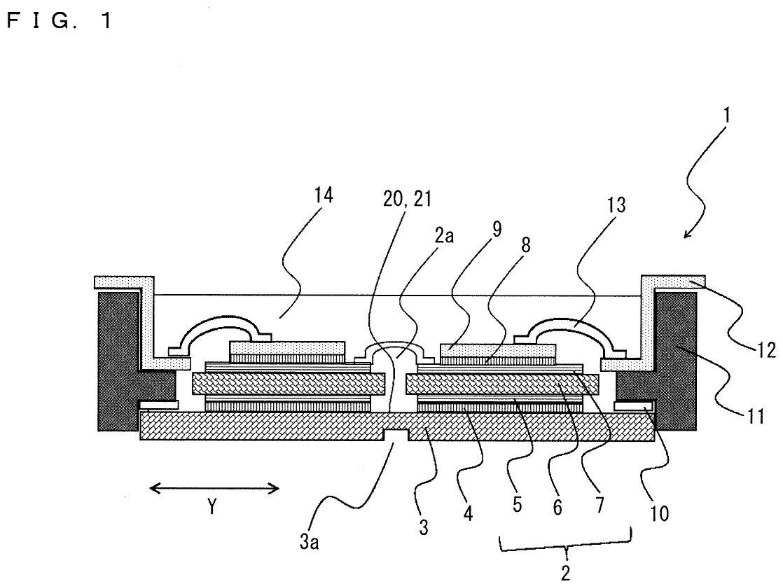

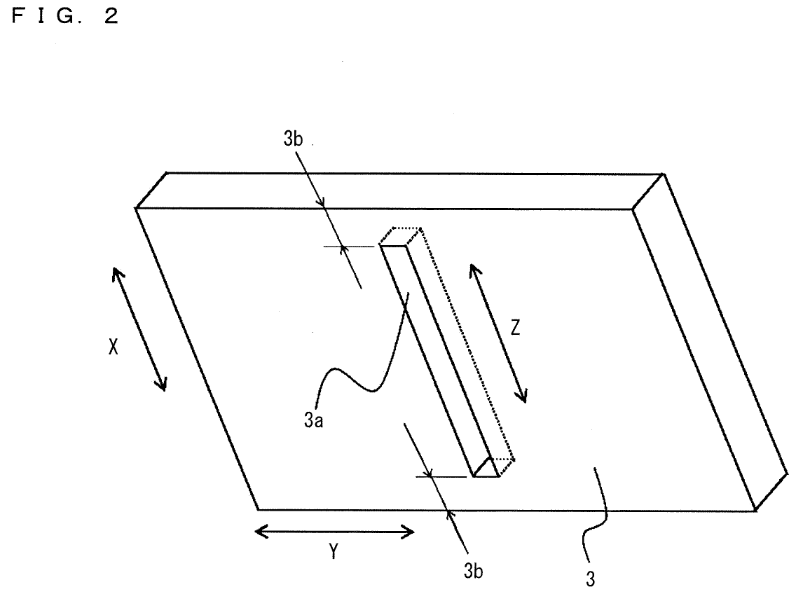

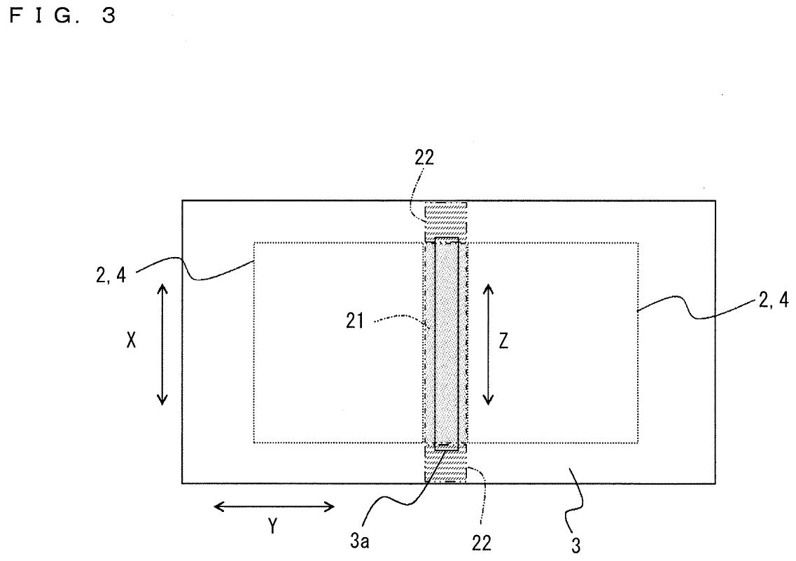

A semiconductor device 1 according to Embodiment 1 will be described with reference to the drawings. FIG. 1 is a cross-sectional view of the semiconductor device 1 according to Embodiment 1. FIG. 2 is a perspective view of a heat sink 3 of the semiconductor device 1 according to Embodiment 1. FIG. 3 is a bottom view of the heat sink 3 of the semiconductor device 1 according to Embodiment 1.

### 1-1. Configuration of Semiconductor Device 1

The semiconductor device 1 includes insulating substrates 2, semiconductor elements 9 bonded to surfaces on one side of the insulating substrates 2, and a heat sink 3 bonded to surfaces on the other side of the insulating substrates 2. In the present embodiment, two pairs of an insulating substrate 2 and a semiconductor element 9 bonded together are included. The number of pairs of the insulating substrate 2 and the semiconductor element 9 bonded together may be one or may be three or more.

### Insulating Substrate

The insulating substrate 2 includes a circuit board 5, an insulating board 6, and a circuit board 7 stacked in this order, and the insulating board 6 is sandwiched between the two circuit boards. The circuit boards are mainly formed of copper and have circuit patterns therein. The insulating board 6 is formed of an insulating ceramic material, such as alumina. An insulator is sandwiched between two types of circuit boards, so that electrical circuits formed by the respective two types of circuit boards do not interfere with each other, and a short and an electrical problem can be prevented. According to this configuration, the two types of circuit boards can form different circuit patterns.

Bonding materials are arranged on opposite surfaces (a surface on one side of the circuit board 7 on the one side and a surface on the other side of the circuit board 5 on the other side in this example) of the insulating substrate 2. While solder is mainly used as the bonding materials, sintered materials including a metal paste, such as a silver paste, may be used. The semiconductor element 9, a capacitor chip, or the like is mounted to a surface on the one side of the insulating substrate 2 on which a bonding material 8 is disposed, and the heat sink 3 is mounted to a surface on the other side of the insulating substrate 2 on which a bonding material 4 is disposed.

In the present embodiment, the insulating substrates 2 are connected to each other via bonding wires 13. For example, an end portion of a bonding wire 13 is mounted to a surface on the one side of each of the insulating substrates 2 to be connected to the circuit board 7 as illustrated in FIG. 1.

### Semiconductor Element

The semiconductor element 9 is bonded to the surface on the one side of the insulating substrate 2. A surface on the other side of the semiconductor element 9 according to the present embodiment is mounted to the above-mentioned surface on the one side of the insulating substrate 2 via the bonding material 8.

One end of the bonding wire 13 is bonded to a surface on the one side of the semiconductor element 9. The other end of the bonding wire 13 is bonded to an external terminal 12. The semiconductor element 9 is electrically connected to an outside by the bonding wire 13.

An IGBT is used as the semiconductor element 9 according to the present embodiment. The IGBT is used for switching of a high voltage and a high current and is for use in motor control, an inverter circuit, and the like. A type of the semiconductor element 9 is not limited to the IGBT and may be a MOSFET.

### Other Configuration of Semiconductor Device

The semiconductor device 1 according to the present embodiment is surrounded by a resin case 11. The resin case 11 is in the form of a rectangular cuboid box. The resin case 11 has a structure capable of containing therein the insulating substrates 2 and the semiconductor elements 9, and, even when a liquid sealing material 14 and the like are caused to flow into the resin case 11, the liquid sealing material 14 and the like do not flow outward. The resin case 11 is formed of resin, such as PPS (polyphenylene sulfide). Another type of resin may be used in place of PPS (polyphenylene sulfide).

As described above, the one end of the bonding wire 13 is mounted to a portion of the surface on the one side of the semiconductor element 9. The other end of the bonding wire 13 is connected to one end of the external terminal 12. The external terminal 12 extends along an inner surface of the resin case 11, and the other end of the external terminal 12 is exposed from the resin case 11 and the sealing material 14 to the outside. The external terminal 12 exposed to the outside comes into contact with another component to enable connection to the external component.

The semiconductor elements 9, the insulating substrates 2, and the bonding wires 13 are surrounded by the resin case 11 and the heat sink 3. An inside of the resin case 11 and the heat sink 3 is filled with the sealing material 14 to protect the semiconductor elements 9, the insulating substrates 2, and the like.

### Heat Sink

A surface on the one side as a surface closer to the insulating substrate 2 of the heat sink 3 is bonded to the surface on the other side of the insulating substrate 2. In the present embodiment, the surface on the one side of the heat sink 3 is bonded to the surface on the other side of the insulating substrate 2 via the bonding material 4. The heat sink 3 is in the form of a rectangular plate (an oblong plate in this example). The heat sink 3 blocks an opening on the other side of the resin case 11. An outer periphery of a surface on the one side of the heat sink 3 is bonded to the resin case 11 by an adhesive 10. The heat sink 3 is formed of metal having good thermal conductivity, such as copper and aluminum. Heat is dissipated from the surface on the other side of the heat sink 3. The surface on the other side of the heat sink 3 may be cooled by a cooling mechanism using a refrigerant, such as air and a cooling fluid.

### Groove of Heat Sink

The insulating substrate 2 is preferably flat or slightly warped to be convex on a side of the semiconductor element 9 when the semiconductor device 1 has been assembled. As described above, the insulating substrate 2 including the circuit board 5 and the insulating board 6 and the heat sink 3 are sequentially stacked and are bonded with solder. The insulating substrate 2 as manufactured sometimes does not have warpage of a desired shape due to a difference in coefficient of linear expansion from the heat sink 3 as manufactured. For example, the insulating substrate 2 can be “reversely warped” to be concave on the side of the semiconductor element 9 when the semiconductor device 1 has been assembled, and, as a result of the above-mentioned warpage, the heat sink 3 or the insulating substrate 2 can be cracked.

In the present embodiment, the heat sink 3 has a groove 3a in the surface on the other side thereof opposite the surface on the one side thereof as a surface closer to the insulating substrate 2 thereof, and the groove 3a is not located in each of portions of the surface on the other side of the heat sink 3 located on opposite sides in a length direction Z of the groove 3a or in a portion of the surface on the other side of the heat sink 3 located on one side in the length direction Z of the groove 3a (in each of the portions on the opposite sides in this example). According to this configuration, suppression of warpage and securement of a strength of the heat sink 3 can both be achieved. Furthermore, since the strength of the heat sink 3 can be maintained, the heat sink 3 itself can be thinned to enable reduction in cost.

In the present embodiment, the groove 3a is not located in each of the portions of the surface on the other side of the heat sink 3 located on the opposite sides in the length direction Z of the groove 3a. According to this configuration, when the heat sink 3 is distorted, a difference in distortion in the length direction can be prevented. Furthermore, a difference in strength between the portions located on the opposite sides in the length direction can be reduced.

In the present embodiment, the groove 3a is located closer to a center of the heat sink 3 in the length direction Z of the groove. Since the groove 3a is located at the center in the length direction Y, the portions on the opposite sides of the groove 3a have equal widths 3b. This can reduce the influence of linear expansion of other components and can prevent the difference in distortion in the length direction when the heat sink 3 is distorted.

In the present embodiment, the groove 3a is located in a region of the surface on the other side of the heat sink 3 opposite an unbonded region 20 of the surface on the one side of the heat sink 3 in which the insulating substrate 2 is not bonded. According to this configuration, the groove 3a is located in the unbonded region 20, so that a direct influence of the groove 3a on a bonded region in which the insulating substrate 2 is bonded is suppressed, and warpage of the insulating substrate 2 and the heat sink 3 in the bonded region can be optimized.

As illustrated in FIG. 3, a plurality of pairs of the insulating substrate 2 and the semiconductor element 9 are arranged to be spaced apart from one another, the groove 3a is located in a region of the surface on the other side opposite a sandwiched unbonded region 21 as the unbonded region sandwiched between adjacent two pairs of the insulating substrate 2 and the semiconductor element 9, and the groove 3a is not located in a region of the surface on the other side opposite an unsandwiched unbonded region 22 as the unbonded region located on each of opposite sides or one side of the sandwiched unbonded region 21 in the length direction Z of the groove 3a. According to this configuration, the groove 3a is located in the sandwiched unbonded region 21 between the adjacent two pairs, so that the influence of distortion in the bonded region of the heat sink 3 corresponding to one of the pairs of the insulating substrate 2 and the semiconductor element 9 on the bonded region of the heat sink 3 corresponding to the other one of the pairs of the insulating substrate 2 and the semiconductor element 9 is suppressed, and warpage of the insulating substrate 2 and the heat sink 3 in the bonded region in each pair can be optimized. The groove 3a is not located in the unsandwiched unbonded region 22 not sandwiched between the adjacent two pairs, so that reduction in strength of the heat sink 3 can be suppressed while the influence on warpage of the insulating substrate 2 and the heat sink 3 in the bonded region in each pair is reduced.

When three or more pairs of the insulating substrate 2 and the semiconductor element 9 are arranged, it is only required to locate the groove 3a in each of sandwiched unbonded regions 21 between adjacent two pairs of the insulating substrate 2 and the semiconductor element 9 and not to locate the groove 3a in each of unsandwiched unbonded regions 22 not sandwiched between the adjacent two pairs of the insulating substrate 2 and the semiconductor element 9.

In the present embodiment, a depth D of the groove 3a is 0.1 mm or more and is ¼ or less of a thickness of the heat sink 3, and a width W of the groove 3a is 0.1 mm or more and ½ or less of the thickness of the heat sink 3. According to this configuration, warpage due to thermal expansion is reduced, and excessive reduction in strength and heat transfer efficiency of the heat sink 3 can be suppressed.

In the present embodiment, the heat sink 3 is in the form of the oblong plate, the length direction Z of the groove 3a is parallel to the transverse direction X of the heat sink 3, and the groove 3a is located in the central portion in the longitudinal direction Y of the heat sink 3. According to this configuration, when the heat sink 3 is distorted, the difference in distortion in the longitudinal direction Y can be prevented.

The heat sink 3 may be in the form other than the form of the oblong plate, such as the form of a square plate, the form of a combination of rectangles, and the form having rounded corners. The length direction Z of the groove 3a may be any proper direction according to the shape of the heat sink 3 and arrangement of the insulating substrates 2.

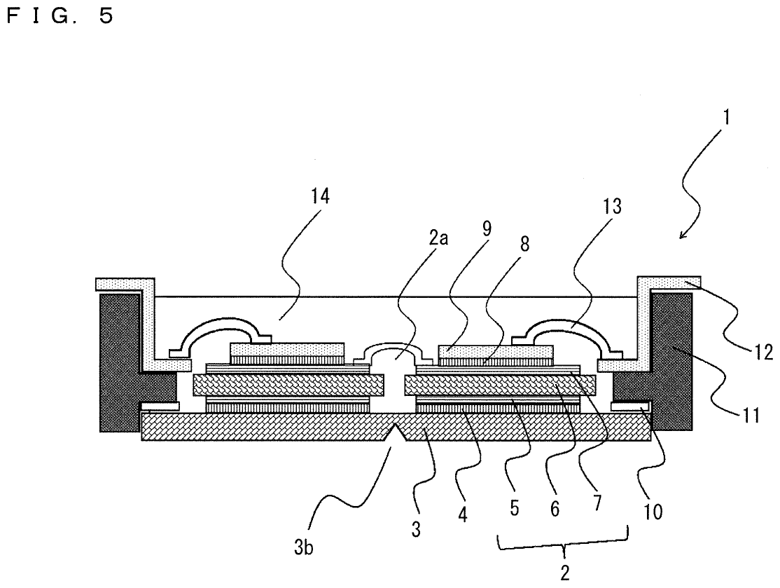

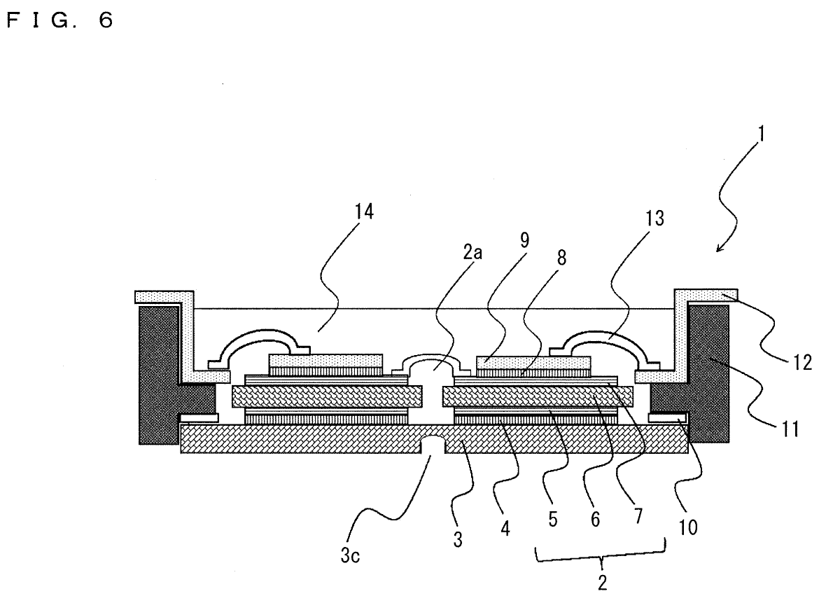

In a modification of Embodiment 1, the groove 3a of the heat sink 3 has a V-shaped cross section as illustrated in FIG. 5 or has a U-shaped cross section as illustrated in FIG. 6. According to this configuration, the influence on the strength and the heat transfer efficiency of the heat sink 3 can be reduced.

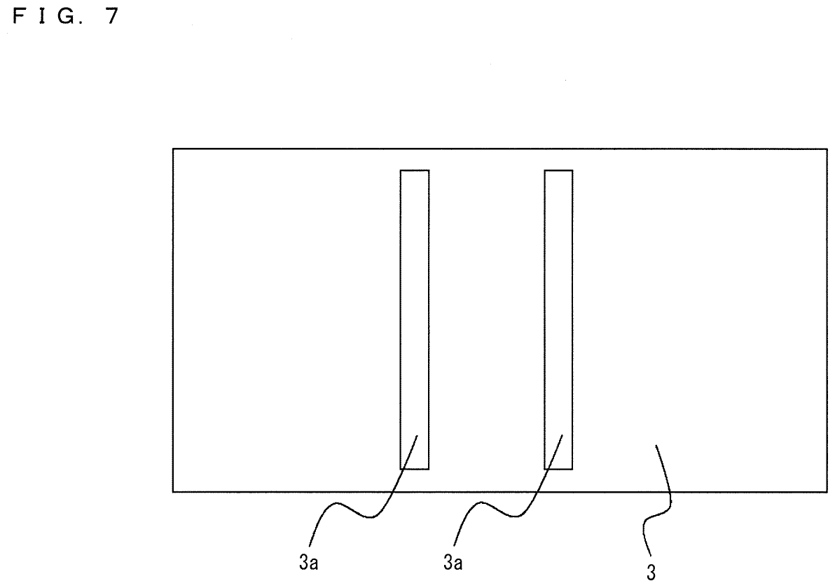

In a modification of Embodiment 1, the groove 3a of the heat sink 3 is located in two or more portions as illustrated in FIG. 7. According to this configuration, a risk of cracking caused by warpage occurring in a process of manufacturing the semiconductor device 1 can be reduced.

While the disclosure has been shown and described in detail, the foregoing description is in all aspects illustrative and not restrictive. It is therefore understood that numerous modifications and variations can be devised.

What is claimed is:

1. A semiconductor device comprising:
an insulating substrate;
a semiconductor element bonded to a surface on one side of the insulating substrate; and
a heat sink bonded to a surface on the other side of the insulating substrate, wherein
the heat sink has at least one groove in a surface on the other side thereof opposite a surface on the one side thereof to which the insulating substrate is bonded, and
the at least one groove is not located in each of portions of the surface on the other side of the heat sink located on opposite sides in a length direction of the at least one groove or in a portion of the surface on the other side of the heat sink located on one side in the length direction of the at least one groove.

2. The semiconductor device according to claim 1, wherein
the at least one groove is located in a region of the surface on the other side of the heat sink opposite a unbonded region of the surface on the one side of the heat sink in which the insulating substrate is not bonded.

3. The semiconductor device according to claim 2, wherein
the insulating substrate and the semiconductor element respectively include a plurality of insulating substrates and a plurality of semiconductor elements paired to form a plurality of pairs of the insulating substrate and the semiconductor element arranged to be spaced apart from one another,
the at least one groove is located in a region of the surface on the other side of the heat sink opposite a sandwiched unbonded region as the unbonded region sandwiched between adjacent two pairs of the insulating substrate and the semiconductor element, and
the at least one groove is not located in a region of the surface on the other side of the heat sink opposite an unsandwiched unbonded region as the unbonded region located on each of opposite sides or on one side of the sandwiched unbonded region in the length direction of the at least one groove.

4. The semiconductor device according to claim 1, wherein
a depth of the at least one groove is 0.1 mm or more and is ¼ or less of a thickness of the heat sink, and a width of the at least one groove is 0.1 mm or more and ½ or less of the thickness of the heat sink.

5. The semiconductor device according to claim 1, wherein
the at least one groove is not located in the portions of the surface on the other side of the heat sink located on the opposite sides of the at least one groove in the length direction of the at least one groove.

6. The semiconductor device according to claim 1, wherein
the heat sink is in a form of an oblong plate,
the length direction of the at least one groove is parallel to a transverse direction of the heat sink, and
the at least one groove is located in a central portion in a longitudinal direction of the heat sink.

7. The semiconductor device according to claim 1, wherein
the at least one groove is located closer to a center of the heat sink in the length direction of the at least one groove.

8. The semiconductor device according to claim 1, wherein
the at least one groove has a U-shaped or a V-shaped cross section.

9. The semiconductor device according to claim 1, wherein
the at least one groove is located in two or more portions.
